(19) United States
(12) Patent Application Publication
(10) Pub. No.: US 2012/0153360 A1
(43) Pub. Date: Jun. 21, 2012

(54) METHOD AND DEVICE FOR REGENERATING A HYDROGEN SENSOR

(75) Inventors: Ketan PATEL, Annecy le Vieux (FR); Didier PIERREJEAN, Groisy (FR)

(73) Assignee: ADIXEN VACUUM PRODUCTS, Annecy (FR)

(21) Appl. No.: 13/328,441

(22) Filed: Dec. 16, 2011

(30) Foreign Application Priority Data
Dec. 17, 2010 (FR) FR 1060731

(51) Int. Cl. H01L 29/78; H01L 21/336

(52) U.S. Cl. 257/253; 438/4; 257/E21.409; 257/E29.255

(57) ABSTRACT

The regeneration method relates to a hydrogen sensor, which comprises a transistor of the MOS type whose gate is covered with a palladium catalyst and which is placed in a low-pressure enclosure. After a leak has been detected, a voltage is imposed on the gate of the transistor by means of an electronic circuit in order to regenerate the catalyst. The electronic circuit comprises a low-frequency DC generator and a switch for changing from the “measurement” mode to the “regeneration” mode, and vice versa.

The present invention relates to a method for regenerating a hydrogen sensor after use for leak detection by hydrogen using a detector operating at low pressure.

After each leak measurement, the hydrogen sensor must be regenerated in order to permit reliable reproduction of the measurements, and to maintain a high sensitivity for the leak detection. The regeneration of the hydrogen sensor consists in neutralizing the hydrogen ions H⁺ trapped on the gate of the transistor contained in the sensor. During the natural process, these hydrogen ions H⁺ combine with oxygen molecules O₂ from the atmosphere. The chemical reaction of the hydrogen ions H⁺ with the oxygen molecules O₂ makes them leave the gate of the transistor and enter the atmosphere. The hydrogen sensor is thus neutralized, and is ready for the next leak test. However, regeneration of the hydrogen sensor by this natural process takes too long and increases the duration of the detection operation, which reduces the frequency of the leak detection cycles. The production efficiency is therefore low. There is a need for a method making it possible to accelerate the regeneration of the hydrogen sensor in order to increase the number of cycles.

However, a problem arises when the measurement is intended to be carried out at a low pressure of between 100 Pa and 5000 Pa, for example 1000 Pa. This is because at low pressures there are not enough oxygen molecules O₂ capable of reacting with the hydrogen ions H. Regeneration of the hydrogen sensor will therefore require an extended duration compared with the natural process, and will commensurately increase the time interval between two measurements. The production efficiency will therefore be less.

It is therefore an object of the present invention to provide a method for regenerating a hydrogen sensor intended for leak detection operating at low pressure. The method permits complete neutralization of the sensor in a short time, which is less than in the natural process known from the prior art.

The invention relates to a method for regenerating a hydrogen sensor, comprising a transistor of the MOS type whose gate is covered with a palladium catalyst, placed in a enclosure at low pressure, that is to say at a pressure of less than 5000 Pa.

According to this method, a voltage is imposed on the gate of the transistor by means of an electronic circuit in order to regenerate the catalyst after a leak has been detected.

According to one aspect, the voltage is imposed on the gate of the transistor in a pulsed mode.

According to another aspect, the transistor is heated to a temperature of between 100° C. and 250° C.

According to yet another aspect, the electronic circuit comprises a switch for changing from the “measurement” mode to the “regeneration” mode, and vice versa.

Another solution to this problem could be to supply oxygen, but this solution is very expensive and commensurately increases the weight of the leak detector. The solution of imposing a voltage with the aid of an electronic circuit has the advantage of being economical, compact and more reliable. It is easy to develop and easy to install in the leak detector. The method can be used with leakage rates which may range from a few Pa·m³/s to 10⁻⁶ Pa·m³/s.

The invention also relates to a leak detection module for implementing the method for regenerating the hydrogen sensor, comprising:

a hydrogen sensor comprising a transistor of the MOS type whose gate is covered with a palladium catalyst, and

a regeneration device comprising:
an electronic circuit comprising:
   a low-frequency DC generator,
   a switch arranged between the low-frequency DC generator and the gate of the MOS-type transistor, the said switch being adapted to impose a voltage on the gate
a control module for controlling the closure and opening of the switch.

According to one variant, the switch is selected from among a relay and a transistor.

Other characteristics and advantages of the present invention will become apparent on reading the following description of an embodiment, which is of course given by way of illustration and without implying limitation, and in the appended drawing in which

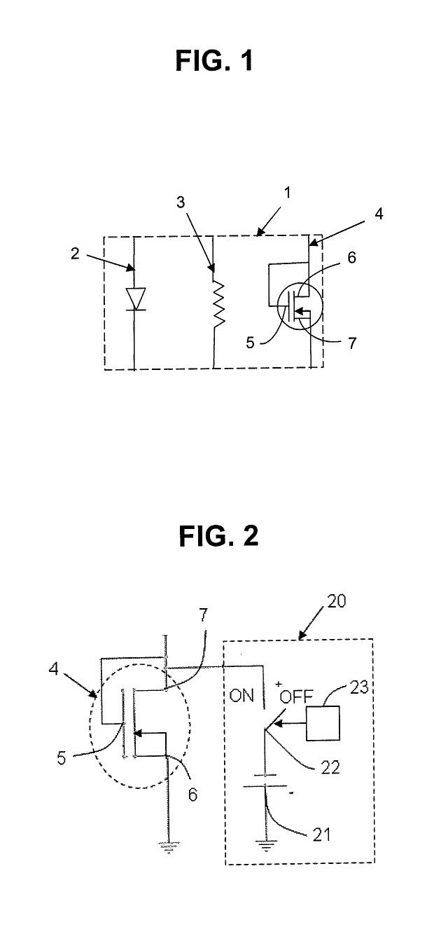

FIG. 1 illustrates an embodiment of a hydrogen sensor,

FIG. 2 illustrates an embodiment of a leak detection module comprising a hydrogen sensor and a device for regenerating the hydrogen sensor,

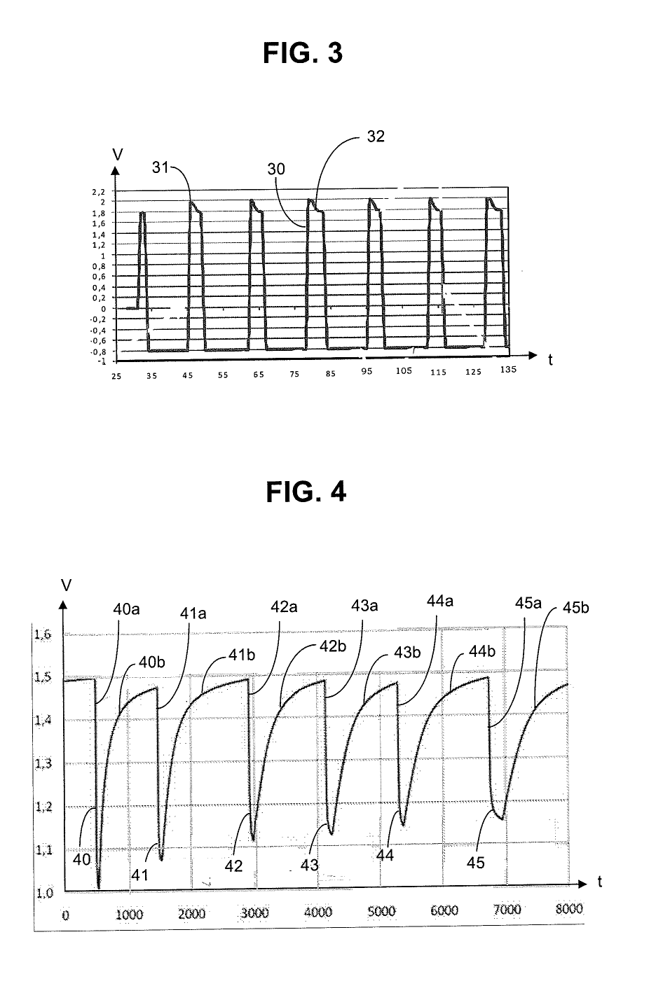

FIG. 3 illustrates the change of the voltage V, in volts, as a function of the time t, in seconds, during the regeneration of the hydrogen sensor by means of the electronic circuit,

FIG. 4 illustrates the change of the voltage V, in volts, at the output of the hydrogen sensor during the measurement and during regeneration by the natural process as a function of time t, in seconds, for different leakage rates.

In the embodiment illustrated in FIGS. 1 and 2, a hydrogen sensor 1 comprises a diode 2, a resistor 3 and a transistor 4.

The transistor 4 is a field effect transistor of the MOSFET type (“Metal Oxide Semiconductor Field Effect Transistor”). The transistor 4 is of the “N” type and has three active electrodes: the gate 5, the drain 6 and the source 7. The transistor 4 modulates the current which flows through it by means of a signal applied to the gate 5, making it possible to control the voltage V between the drain 6 and the source 7. The gate 5 is covered with a palladium-based catalyst sensitive to hydrogen. A constant current is applied to the drain 6 of the transistor 4 of the hydrogen sensor 1 in order to bias the transistor 4. The quantity of hydrogen ions H⁺ trapped on the gate 5 modifies the bias of the transistor, which makes it possible to evaluate the flow of hydrogen molecules H₂ entering into contact with the gate 5. When there are no hydrogen molecules H₂ present, the output voltage V of the transistor 4 is stable at its maximum value. The value of the voltage V depends on the current applied to the drain 6. When the H₂ molecules arrive in contact with the palladium catalyst of the gate 5, they are cleaved to give H⁺ ions. The H⁺ ions diffuse through the palladium catalyst and become trapped on the gate 5 of the transistor 4. This causes a variation in the drain 6—source 7 resistance of the transistor 4, which leads to a decrease in the voltage V of the gate 5 proportional to the concentration of hydrogen ions H. On the basis of calculating the derivative of the decrease in the voltage V as a function of time, a leakage rate can be calculated. The drain 6—source 7 resistance of the transistor 4 thus constitutes the sensitive part of the sensor 1 fulfilling the function of measuring the leak. By injecting a constant current into the drain 6 of the transistor 4, a value of the voltage V is obtained representing the quantity of ions H⁺ trapped by the gate 5, which makes it possible to evaluate the flow of hydrogen arriving in contact with the gate 5.

FIG. 2 represents a leak detection module for carrying out a method for regenerating the hydrogen sensor 1.

The leak detection module comprises the hydrogen sensor 1 and a regeneration device 20.

The regeneration device 20 comprises an electronic circuit and an electronic control module 23. The electronic circuit comprises a low-frequency generator 21 and a switch 22.

The control module 23 is adapted to cause opening of the switch 22 in detection mode and closure of the switch 22 in regeneration mode.

The control module 23 comprises a mathematical model for calculating the leakage rate on the basis of the variation in the drain 6—source 7 voltage V of the transistor 4 as a function of time. Since the number of hydrogen molecules H₂ which strike the active surface of the gate 5 of the transistor 4 is proportional to the pressure, the drain 6—source 7 resistance will therefore be proportional to the absolute hydrogen pressure around the transistor 4. With a residual pressure of 1000 Pa, a monolayer of hydrogen, atoms is formed in about 25 μs.

A heating resistor 3 makes it possible to heat the hydrogen sensor 1 to a temperature of 130° C., for example, which advantageously increases the sensitivity of the hydrogen sensor 1. The temperature must not however exceed 250° C., this limit being imposed by the silicon of the transistor 4. Tests have shown that a temperature of 180° C. can be used without damage. By way of example, the heating resistor of the hydrogen sensor 1 may have a value of between 70 Ω and 80 Ω; at atmospheric pressure, the heating current will be from 60 to 80 mA, i.e. a heating power of approximately 0.4 W.

A diode 2 and the associated heating resistor 3 are used to regulate the temperature of the hydrogen sensor 1. For reasons of safety, a gas mixture composed of 95% nitrogen and 5% hydrogen is used, which is not brought into contact with the hydrogen sensor 1 until a temperature of 130° C. has been reached, in order to avoid any degradation of the catalyst. It is also in order to preserve the catalyst that the hydrogen sensor 1 is used at very low pressure, so as to be in contact with only a small quantity of hydrogen.

The electronic circuit imposes a voltage U on the gate 5 of the transistor 4 of the hydrogen sensor 1. The voltage U is imposed by the low-frequency DC generator 21 associated with the ON-OFF switch 22. The switch 22 may for example be a relay, a transistor or a system of the same type. The switch 22 is arranged between the low-frequency DC generator 21 and the gate 5 of the transistor 4.

In this configuration, the sensor 1 can operate in “measurement” mode (switch set to OFF), which allows leak detection, or in “regeneration” mode (switch set to ON), which makes it possible to neutralize the sensor. The switch 22 is thus adapted to impose a voltage on the gate 5 of the transistor 4 when the switch 22 is closed.

This device makes it possible to regenerate the hydrogen sensor 1 with a very short response time. This device is very economical in so far as it only requires an external electronic drive circuit.

Once the measurement has been carried out, it is necessary to remove the hydrogen ions H⁺ trapped by the gate 5 of the transistor 4, so that the hydrogen sensor 1 is ready for the next leak test. For regeneration of the sensor, the control module causes closure of the switch, and a voltage U is thus imposed with the aid of the electronic circuit. The voltage U is imposed by the low-frequency DC generator 21 associated with the switch 22.

FIG. 3 illustrates the change in the output voltage V of the transistor 4 as a function of time t. At the start of the leak detection, the gate 5 of the transistor 4 is brought to the required temperature by means of the heating resistor 3. A constant current is then applied to the gate 5 of the transistor 4, which produces a voltage V which is representative of its state (curve part 30). When there are no hydrogen molecules H₂ present, the output voltage V is stable at its maximum value 31. Once the hydrogen molecules H₂ reach the gate 5 and are absorbed in the palladium catalyst, the voltage V starts to decrease (curve part 32) as a function of the concentration of hydrogen ions H⁺ absorbed. The leakage rate is calculated on the basis of the slope, represented by the derivative, of the curve of voltage V as a function of time t, and the result of the measurement is displayed.

When the leak test is finished, the hydrogen molecules H₂ cease to reach the gate 5 of the transistor 4, and the voltage V starts to increase slowly and return to its initial value, which is an indication that the sensor 1 has been regenerated. As explained above, however, the natural process takes a long time at low pressure. It is now that a voltage U is imposed on the gate 5 of the transistor 4 by means of the electronic circuit, which accelerates the neutralization of the hydrogen ions H⁺ and the return to the equilibrium voltage 31 of the sensor. This imposed voltage U makes the hydrogen ions H⁺ react and neutralizes the gate 5 of the transistor 4 of the hydrogen sensor 1. Once the hydrogen sensor 1 has been fully regenerated, the control module 23 causes the switch 22 to open, and the imposition of the voltage U is stopped. The hydrogen sensor 1 is now again ready to carry out the next leak detection test. The switch 22 makes it possible to fully isolate the electronic circuit 20 from the gate 5 of the transistor 4 during the leak measurement.

A voltage U is imposed on the gate 5 of the transistor 4 in a pulsed mode in order to obtain more rapid forced regeneration. The level of the voltage U imposed and the time interval between two impositions depends on the type of leak and the application desired by the client. This method allows reproducible and reliable regeneration of the hydrogen sensor 1 by neutralization.

FIG. 4 illustrates the results obtained during tests of regeneration by the natural process for different values of the leakage rate.

Tests were carried out, by way of example, for the following leakage rates:

| | |
|---|---|
| 1.13 · 10⁻² Pa · m³ · s | curve 40 |
| 6.08 · 10⁻³ Pa · m³ · s | curve 41 |
| 4.02 · 10⁻³ Pa · m³ · s | curve 42 |
| 3.31 · 10⁻³ Pa · m³ · s | curve 43 |
| 3.04 · 10⁻³ Pa · m³ · s | curve 44 |
| 2.30 · 10⁻³ Pa · m³ · s | curve 45 |

FIG. 4 shows a substantially vertical first part 40a-45a of the curve, corresponding to the leakage rate measurement, and a rounded second part 40b-45b of the curve corresponding to the step of regeneration by the natural process.

This regeneration by the natural process takes a time of the order of 1000 seconds. The forced regeneration by means of the electronic circuit 20, as illustrated in FIG. 3, makes it possible to divide this duration by 200.

The present invention is of course not limited to the embodiments described, but may be subject to numerous variants apparent to the person skilled in the art without departing from the spirit of the invention.

1. Method for regenerating a hydrogen sensor, comprising a transistor of the MOS type whose gate is covered with a palladium catalyst, placed in a enclosure having a pressure less than 5000 Pa, wherein a voltage is imposed on the gate of the transistor by means of an electronic circuit in order to regenerate the catalyst after a leak has been detected.

2. Method according to claim 1, wherein the voltage is imposed on the gate of the transistor in a pulsed mode.

3. Method according to claim 1, wherein the transistor is heated to a temperature of between 100° C. and 250° C.

4. Method according to claim 1, wherein the electronic circuit comprises a switch for changing from the “measurement” mode to the “regeneration” mode, and vice versa.

5. Leak detection module for implementing the method for regenerating a hydrogen sensor, comprising:
a hydrogen sensor comprising a transistor of the MOS type whose gate is covered with a palladium catalyst, and
a regeneration device comprising:
an electronic circuit comprising:
a low-frequency DC generator,
a switch arranged between the low-frequency DC generator and the gate of the MOS-type transistor, the said switch being adapted to impose a voltage on the gate of the transistor when the switch is closed, and
a control module for controlling the closure and opening of the switch.

6. Device according to claim 5, wherein the switch is selected from among a relay and a transistor.
